(19) United States
(12) Patent Application Publication
(10) Pub. No.: US 2020/0089032 A1
(43) Pub. Date: Mar. 19, 2020

(54) COLOR FILTER, AND MANUFACTURING METHOD THEREOF AND DISPLAY PANEL

(71) Applicant: HKC Corporation Limited, Shenzhen (CN)

(72) Inventor: Beizhou Huang, Shenzhen (CN)

(21) Appl. No.: 16/241,999

(22) Filed: Jan. 8, 2019

Related U.S. Application Data
(63) Continuation of application No. PCT/CN2018/111326, filed on Oct. 23, 2018.

(30) Foreign Application Priority Data
Sep. 13, 2018 (CN) 201811066930.1

(51) Int. Cl. G02F 1/1362; G02F 1/1339; G02B 5/20; G03F 7/00

(52) U.S. Cl. CPC G02F 1/1362; G02F 1/1339; G02F 2001/136222; G03F 7/0007; G02B 5/201

(57) ABSTRACT

The disclosure discloses a color filter, a manufacturing method thereof and a display panel. the first attachment region is defined with a second color layer, and the second color layer in the first attachment region is defined with a first color layer thereon, the second attachment region is defined with the second color layer thereon, and the third attachment region is defined with a third color layer thereon, a main spacer is defined on the upper surface of the first color layer thereon, an auxiliary spacer is defined on an upper surface of the second color layer in the second attachment region, and is defined on an upper surface of the third color layer in the third attachment region, the height of the upper surface of the main spacer from the substrate is greater than the height of the upper surface of the auxiliary spacer from the substrate.

### CROSS REFERENCE TO RELATED APPLICATIONS

The present application is a Continuation Application of PCT Application No. PCT/CN2018/111326 filed on Oct. 23, 2018, which claims the benefit of Chinese Patent Application No. 201811066930.1 filed on Sep. 13, 2018. All the above are hereby incorporated by reference.

### FIELD

The disclosure relates to the field of liquid crystal display technology, and in particular, relates to a color filter and a manufacturing method thereof and a display panel.

### BACKGROUND

A display panel of a liquid crystal display includes an array substrate on which a thin film transistor (TFT), a liquid crystal layer, and a color filter (CF) are manufactured. A plurality of spacers are defined between the color filter and the array substrate, and the heights of the spacers are not consistent, so that the liquid crystal layer between the array substrate and the color filter are more uniform and have a certain filling amount, thus avoiding the phenomenon of unevenness display caused by liquid crystal drop error. However, in order to ensure the segment difference between the spacers, the employed structure is complicated and the manufacturing is costly.

### SUMMARY

The main purpose of the present disclosure is to provide a color filter, which aims to make the spacer in the color filter be simple in structure and low in manufacturing cost while satisfying the segment difference requirement.

In order to achieve the above object, a color filter proposed in the present disclosure includes:

a substrate, defined with a first attachment region, a second attachment region and a third attachment region;

a color filter layer, including a first color layer, a second color layer, and a third color layer, and the first attachment region is defined with the second color layer thereon, and the second color layer in the first attachment region is defined with the first color layer thereon, the second attachment region is defined with the second color layer thereon, and the third attachment region is defined with the third color layer thereon; and

a spacer, including a main spacer and an auxiliary spacer, and the main spacer is defined in an upper surface of the first color layer, the auxiliary spacer is defined in an upper surface of the second color layer in the second attachment region, and is defined in an upper surface of the third color layer in the third attachment region,

the height of the upper surface of the main spacer from the substrate is greater than the height of the upper surface of the auxiliary spacer from the substrate.

Optionally, the upper surface of the second color layer defined in the second attachment region is higher than the upper surface of the third color layer defined in the third attachment region.

Optionally, the first color layer is a blue layer, the second color layer is a green layer, and the third color layer is a red layer.

Optionally, the first attachment region, the second attachment region and the third attachment region are sequentially defined in parallel.

Optionally, the heights of the upper surfaces of the first color layer, the second color layer, and the third color layer from the substrate decreases sequentially.

Optionally, the upper surface of the second spacer defined in the second attachment region is higher than the upper surface of the secondary spacer defined in the third attachment region.

Optionally, a black matrix layer is defined on the substrate, and the black matrix layer defines the first attachment region, the second attachment region and the third attachment region on the substrate.

The disclosure also provides a manufacturing method of the color filter, which includes the following steps:

exposing a third attachment region of the substrate to form the third color layer;

exposing the second attachment region and the first attachment region on the substrate to form the second color layer;

exposing the second color layer in the first attachment region on the substrate to form the first color layer.

The disclosure also provides a manufacturing method of the color filter, steps of the method includes:

exposing the second attachment region and the first attachment region on the substrate to form the second color layer;

exposing a third attachment region of the substrate to form the third color layer;

exposing the second color layer in the first attachment region on the substrate to form the first color layer.

The disclosure also provides a display panel, which includes an array substrate and the color filter, the array substrate abuts on one end of the main spacer facing away from the substrate;

the color filter including:

a substrate, defined with a first attachment region, a second attachment region and a third attachment region;

a color filter layer, including a first color layer, a second color layer, and a third color layer, and the first attachment region is defined with the second color layer thereon, and the second color layer in the first attachment region is defined with the first color layer thereon, the second attachment region is defined with the second color layer thereon, and the third attachment region is defined with the third color layer thereon; and

a spacer, including a main spacer and an auxiliary spacer, and the main spacer is defined in an upper surface of the first color layer, the auxiliary spacer is defined in an upper surface of the second color layer in the second attachment region, and is defined in an upper surface of the third color layer in the third attachment region,

the height of the upper surface of the main spacer from the substrate is greater than the height of the upper surface of the auxiliary spacer from the substrate.

According to the technical scheme of the disclosure, the substrate of the color filter is defined with a first attachment region, a second attachment region and a third attachment region. Generally, the first attachment region, the second attachment region and the third attachment region are respectively defined with a first color layer, a second color layer and a third color layer, and the first color layer, the second color layer and the third color layer in the first attachment region, the second attachment region and the third attachment region are also respectively defined with a main spacer and an auxiliary spacer. In order to make the main spacer in the first attachment region and the auxiliary spacer in the second attachment region and the third attachment region meet the designing requirements of segment difference in the aspect of height, it is necessary to increase the distance between the main spacer and the substrate. According to the technical scheme of the present disclosure, a second color layer is firstly defined in the first attachment region, and then a first color layer is defined on the upper surface of the second color layer, so that the distance between the upper surface of the first color layer and the substrate is increased without changing the original thickness of the first color layer. Thereby, the segment difference between the main spacer and the auxiliary spacer in height, ensuring that the segment difference meets the design requirements, enabling the liquid crystal filled between the color filter and the array substrate to meet the design and use requirements.

Furthermore, by adjusting the height of the upper surfaces of the different color layers in the color filter layer from the substrate, the segment difference between the spacers is increased, so that there is no need to change the mould configured to making the spacers during original process. The second color layer is directly formed in the first attachment region and the second attachment region by original manufacture process, and then the first color layer is formed on the second color layer or the third color layer, defined in the first attachment region. Thereby, the segment difference between the spacers is ensured without changing original manufacture process of the color filter and further reducing the cost of production and manufacturer of the color filter.

### BRIEF DESCRIPTION OF THE DRAWINGS

To illustrate the technical solutions according to the embodiments of the present invention or in the prior art more clearly, the accompanying drawings for describing the embodiments or the prior art are introduced briefly in the following. Apparently, the accompanying drawings in the following description are only about some embodiments of the present invention, and persons of ordinary skill in the art can derive other drawings from the accompanying drawings without creative efforts.

FIG. 1 is a partial structural diagram of a color filter in an embodiment of the present disclosure;

FIG. 2 is a sectional view taken along A-A in FIG. 1;

FIG. 3 is a partial structural diagram of a color filter in another embodiment of the present disclosure;

FIG. 4 is a sectional view taken along B-B in FIG. 3.

### BRIEF DESCRIPTION OF THE DRAWINGS

| Label | Name |
|---|---|
| 100 | color filter |
| 10 | substrate |
| 11 | the first attachment |
| | region |
| 13 | the second |
| | attachment region |
| 15 | the third |
| | attachment region |
| 30 | color filter layer |
| 31 | first color layer |
| 33 | second color layer |
| 33a | second color layer |
| 35 | third color layer |
| 50 | spacer |
| 51 | main spacer |
| 53 | auxiliary spacer |
| 70 | black matrix layer |

The realization, functional features and advantages of the purpose of this disclosure will be further described with reference to the accompanying drawings in conjunction with the embodiments.

### DETAILED DESCRIPTION OF THE EMBODIMENTS

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present disclosure without creative efforts shall fall within the protection scope of the present disclosure.

It should be noted that all directional indications (such as up, down, left, right, front, back, etc.) in the embodiments of the present disclosure are only set to explain the relative positional relationship, movement, etc. between the components in a certain posture (as shown in the drawings), and if the specific posture changes, the directional indication changes accordingly.

In addition, in this disclosure, the descriptions such as “first” and “second” are set for the purpose of description only, and are not to be understood as indicating or implying its relative importance or implicitly indicating the number of indicated technical features. Thus, features defining “first” and “second” may explicitly or implicitly include at least one such feature. In addition, the technical solutions between the various embodiments may be combined with each other, but must be based on what one of ordinary skill in the art can achieve. When the combination of technical solutions is contradictory or impossible to achieve, it should be considered that the combination of such technical solutions does not exist and is not within the scope of protection required by this disclosure.

The present disclosure proposes a color filter 100. The color filter 100 includes a spacer 50, in the display panel of the liquid crystal display, a color filter is defined as facing the array substrate, and the spacer 50 is configured to support the array substrate. Defining the spacers 50 in different heights may uniform the flowing liquid crystal layer between the color filter and the array substrate, and may ensure the filling amount of liquid crystal and avoid the adverse effect on the product caused by liquid crystal dropping error.

The segment difference between the spacers 50 is determined by the thickness of the spacers 50 themselves and the height of the upper surface of the color filter layer 30 from the substrate 10. In the manufacture process of the spacers 50, Gray Tone masks or Half Tone masks are used in combination with different exposure levels to control the position and thickness of the spacers 50. When to increase the segment difference between the spacers 50 by adjusting the thickness of the spacers 50, it is necessary to change different Gray Tone masks or Half Tone masks, Gray Tone masks or Half Tone masks are relatively expensive, thus increasing the manufacturing cost of the color filter 100.

In an embodiment of the present disclosure, the color filter 100 includes:

a substrate 10, defined with a first attachment region 11, a second attachment region 13 and a third attachment region 15;

a color filter layer 30, including a first color layer 31, a second color layer 33 and a third color layer 35, the first attachment region 11 is defined with a second color layer 33a, and the second color layer 33a in the first attachment region 11 is defined with a first color layer 31, the second attachment region 13 is defined with a second color layer 33 thereon, and the third attachment region 15 is defined with a third color layer 35 thereon; and

a spacer 50, including a main spacer 51 and an auxiliary spacer 53, the main spacer 51 is defined on the upper surface of the first color layer 31, the auxiliary spacer is defined in an upper surface of the second color layer in the second attachment region, and is defined on an upper surface of the third color layer in the third attachment region,

the height of the upper surface of the main spacer 51 from the substrate 10 is greater than the height of the upper surface of the auxiliary spacer 53 from the substrate 10.

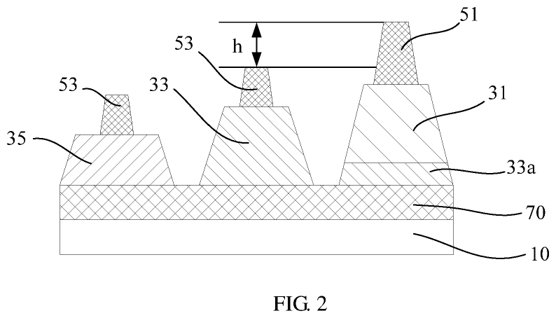

According to the technical scheme of the disclosure, the substrate 10 of the color filter 100 is defined with a first attachment region 11, a second attachment region 13 and a third attachment region 15. Generally, the first attachment region 11, the second attachment region 13, and the third attachment region 15 are respectively defined with a first color layer 31, a second color layer 33 and a third color layer 35, and the first color layer 31, the second color layer 33, and the third color layer 35 in the first attachment region 11, the second attachment region 13, and the third attachment region 15 are also respectively defined with a main spacer 51 and an auxiliary spacer 53. In order to make the main spacer 51 in the first attachment region 11 and the auxiliary spacer 53 in the second attachment region 13 and the third attachment region 15 meet the designing requirements of segment difference in the aspect of height, it is necessary to increase the distance between the main spacer 51 and the substrate 10. Referring to FIG. 2, according to the technical scheme of the present disclosure, the second color layer 33a is defined firstly in the first attachment region 11, and then the first color layer 31 is defined on the upper surface of the second color layer 33a, so that the distance between the upper surface of the first color layer 31 and the substrate 10 is increased without changing the original thickness of the first color layer 31. Thereby, the segment difference h between the main spacer 51 and the auxiliary spacer 53 in height, ensuring that the segment difference meets the design requirements, enabling the liquid crystal filled between the color filter and the array substrate to meet the design and use requirements.

According to the technical scheme of the present disclosure, the segment difference between the spacers 50 is increased by adjusting the height of the upper surface of the different color layers in the color filter layer 30 from the substrate 10, so that the Gray Tone masks or Half Tone masks configured to manufacture the spacers 50 in the original process is not required to be changed, The second color layer 33 is directly formed in the first attachment region 11 and the second attachment region 13 by original manufacture process, and then the first color layer is formed on the second color layer or the third color layer, defined in the first attachment region. Thereby, the segment difference between the spacers is ensured without changing original manufacture process of the color filter and further reducing the cost of production and manufacturer of the color filter.

The color filter layer 30 has three color layers of different colors, namely, the first color layer 31, the second color layer 33, and the third color layer 35. Specifically, referring to FIG. 2, the first color layer 31, the second color layer 33, and the third color layer 35 may respectively be a blue layer, a green layer, and a red layer. In this embodiment, a main spacer 51 is defined on upper surface of the blue layer, and the main spacer 51 on the blue layer supports the array substrate, an auxiliary spacer 53 is defined on the upper surfaces of the green layer and the red layer respectively. According to the technical scheme of the present disclosure, a green layer is defined between the blue layer and the substrate 10 so as to increase the height of the upper surface of the main spacer 51, thereby making the segment difference between the upper surfaces of the main spacer 51 and the auxiliary spacer 53 on the blue layer meet the production and use requirements.

The first color layer 31, the second color layer 33, and the third color layer 35 in the technical scheme of the present disclosure may also respectively be a blue layer, a red layer, and a green layer. It can be understood that, the technical scheme of the present disclosure may ensure that the segment difference between the main spacer 51 and the auxiliary spacer 53 meets the required requirements, but does not limit the colors of the first color layer 31, the second color layer 33 and the third color layer 35. That is, the first color layer 31, the second color layer 33 and the third color layer 35 may also be color layers of other colors in the technical scheme of the present disclosure, so that the display panel applying the color filter 100 may meet other different display requirements. The technical schemes that the first color layer 31, the second color layer 33, and the third color layer 35 are other different combinations of blue layers, green layers, and red layers are also within the scope of protection of this disclosure.

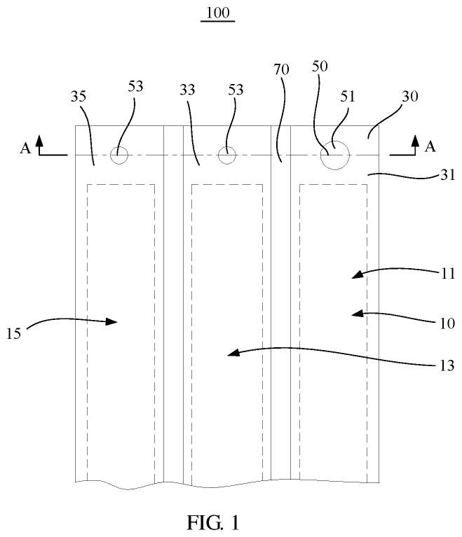

Referring to FIGS. 1 and 2, in the embodiment of the present disclosure, the first attachment region 11, the second attachment region 13, and the third attachment region 15 are sequentially defined in parallel, so that the first color layer 31 defined in the first attachment region 11, the second color layer 33 defined in the second attachment region 13, and the third color layer 35 defined in the third attachment region 15 are sequentially defined in parallel. In this embodiment, the upper surface of the main spacer 51 in the first color layer 31 and the upper surface of the auxiliary spacer 53 of the adjacent second color layer 33 meet the segment difference requirement. The height of the upper surface of the secondary spacer 53 on the second color layer 33 and the third color layer 35 may be the same or may be defined differently according to specific requirements. Optionally, the height of the upper surfaces of the auxiliary spacer 53 in the second color layer 33 and the third color layer 35 is defined to be inconsistent so that the liquid crystal layer filling between the array substrate and the color filter is more uniform. Specifically, the upper surface of the second color layer 33 in the second attachment region 13 is higher than the upper surface of the third color layer 35 in the third attachment region 15 so that the upper surface of the auxiliary spacer 53 in the second color layer 33 is higher than the upper surface of the auxiliary spacer 53 in the third color layer 35.

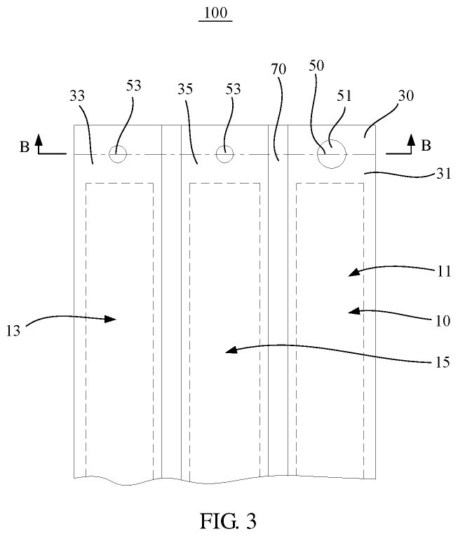

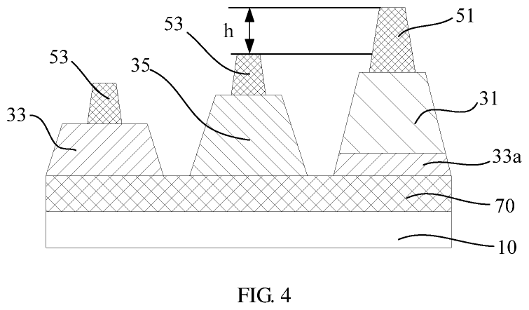

Referring to FIGS. 3 and 4, in another embodiment of the present disclosure, the first attachment region 11, the third attachment region 15, and the second attachment region 13 are sequentially defined in parallel. In this embodiment, the first color layer 31 in the first attachment region 11 is a blue layer, the third color layer 35 defined in the third attachment region 15 is a green layer, the second color layer 33 defined in the second attachment region 13 is a red layer, and the second color layer 33a defined in the first attachment region 11 is also a red layer.

Specifically, in one embodiment, the height of the upper surface of the main spacer 51 in the first attachment region 11 from the substrate 10 is greater than the height of the upper surface of the auxiliary spacer 53 in the second attachment region 13 from the substrate 10. And the height of the upper surface of the auxiliary spacer 53 in the second attachment region 13 from the substrate 10 is greater than the height of the upper surface of the auxiliary spacer 53 in the third attachment region 15 from the substrate 10. The segment difference between the main spacer 51 and the auxiliary spacer 53 and the segment difference between the two auxiliary spacers 53 are defined according to specific requirements and are not limited here.

Referring to FIG. 2, the heights of the upper surfaces of the first color layer 31, the second color layer 33, and the third color layer 35 from the substrate 10 sequentially decreases. The height difference between the first color layer 31, the second color layer 33 and the third color layer 35 may also increase the segment difference between the spacers 50 so as to a certain extent so that the segment difference meets the design requirements, further reducing the manufacturing cost and simplify the manufacturing process.

Further, the thicknesses of the first color layer 31, the second color layer 33, and the third color layer 35 may also be different. By changing the thicknesses of the first color layer 31, the second color layer 33, and the third color layer 35, the light output rate of the backlight module in different color layers may be adjusted, thereby adjusting the color temperature displayed through the color filter 100 to achieve different display effects. In one embodiment, the thicknesses of the first color layer 31, the second color layer 33, and the third color layer 35 are sequentially decreased.

It will be understood that the thicknesses of the first color layer 31, the second color layer 33, and the third color layer 35 may also be adjusted as needed to achieve a wide color gamut or other display effects.

In the embodiment of the present disclosure, a black matrix layer 70 is defined on the substrate 10, and the black matrix layer 70 defines a first attachment region 11, a second attachment region 13, and a third attachment region 15 on the substrate 10. The black matrix layer 70 may prevent the color filter from leaking light and increase the contrast between the color layers of the color filter layer 30.

The disclosure also provides a method for manufacturing the color filter 100, which is the color filter 100 described above.

The manufacturing method of the color filter 100 includes the following steps:

manufacturing a black matrix layer 70 on the substrate 10;

The black matrix layer 70 defines pixel areas on the substrate 10 and defines the first attachment region 11, the second attachment region 13 and the third attachment region 15 in each pixel area.

Next, performing the following steps on the substrate 10 which is defined with the black matrix layer 70:

S10: forming the third color layer 35 by exposing the third attachment region 15 of the substrate 10;

S20: exposing the second attachment region 13 and the first attachment region 11 on the substrate 10 to form the second color layer 33;

As shown in FIG. 2, specifically, the second color layer 33 is formed by exposure in the second attachment region 13, while the second color layer 33a is formed by exposure in the first attachment region 11. The thicknesses of the second color layer 33 in the second attachment region 13 and the second color layer 33a in the first attachment region 11 may be adjusted according to the exposure degree to obtain a specified thickness.

S30: exposing the second color layer 33 in the first attachment region 11 on the substrate 10 to form the first color layer 31.

Referring to FIGS. 1 and 2, in this embodiment, the first attachment region 11, the second attachment region 13, and the third attachment region 15 are sequentially defined in parallel, with the first color layer 31, the second color layer 33, 33a, and the third color layer 35 respectively being a blue layer, a green layer, and a red layer. In step S10 of this embodiment, the step of forming the third color layer 35 by exposing the third attachment region 15 of the substrate 10 includes exposing the third attachment region 15 to form a red layer by using a corresponding mask. Specifically, the step includes: firstly, coating a red photoresist on the substrate 10 on which the black matrix layer 70 is defined; vacuum drying, baking, cooling, exposure and development, cover a mask above the red photoresist during exposure, and exposing with ultraviolet rays, control the thickness of the red layer on the third attachment region 15 by adjusting the exposure intensity and the area of light transmission regions on the mask.

In step S20 of this embodiment, the step of exposing the second attachment region 13 and the first attachment region 11 on the substrate 10 to form the second color layer 33 includes exposing the second attachment region 13 and the first attachment region 11 to form a green layer using a corresponding mask. The specific steps are substantially the same as the above-mentioned steps of manufacturing a red layer, except the light-transmitting regions on the mask. The light-transmitting regions are different on the mask to control the forming of the green layers of required thicknesses formed on the second attachment region 13 and the first attachment region 11, respectively.

Step 30 in this embodiment: the step of exposing the second color layer 33 in the first attachment region 11 on the substrate 10 to form the first color layer 31 includes exposing the green layer in the first attachment region 11 to form a blue layer using a corresponding mask. The specific steps are substantially the same as the above-mentioned step of making a red layer, except the light-transmitting areas on the mask. The light-transmitting areas on the mask are different to control the blue layer to form a desired thickness of the blue layer on the green layer in the first attachment region 11.

After the above steps, the spacer 50 is formed on the substrate 10 which is defined with the color filter layer 30, so that the segment difference h between the main spacer 51 and the auxiliary spacer 53 in the spacers 50 may meet the design requirements.

The longitudinal cross section of the main spacer 51 is trapezoidal, so that the main spacer 51 may be compressed under the force of the array substrate, keeping it with a certain adjustment margin. It can be understood that the main spacer 51 may also be defined in other shapes, which may also meet the use requirements. The shape of the auxiliary spacer 53 coincides with the shape of the main spacer 51.

The steps of the manufacturing method of the color filter 100 of the present disclosure may further include:

exposing the second attachment region 13 and the first attachment region 11 on the substrate 10 to form the second color layer 33;

forming the third color layer 35 by exposing the third attachment region 15 of the substrate 10;

exposing the second color layer 33 in the first attachment region 11 on the substrate 10 to form the first color layer 31.

In this step, the first color layer 31, the second color layer 33, and the third color layer 35 may also be blue layers, green layers, and red layers defined sequentially in parallel, respectively. The specific implementation mode is similar to that of the above embodiments and will not be described in detail here.

It can be understood that the above-mentioned first color layer 31, second color layer 33 and third color layer 35 are not limited to the arrangement of the above-mentioned color layers, but may also be other arrangements of the blue layer, green layer and red layer, or may be not limited to the blue layer, green layer and red layer, and may also be color layers of other colors, all the above technical schemes are within the scope of protection of this disclosure.

The disclosure also provides a display panel which includes an array substrate and a color filter 100. The specific structure of the color filter 100 refers to the above embodiments. Since the display panel employs all the technical solutions of all the above embodiments, it has at least all the beneficial effects brought about by the technical solutions of the above embodiments and will not be described in detail here. The array substrate abuts one end of the main spacer 51 facing away from the substrate 10. The display panel may be a liquid crystal panel.

The above is only the preferred embodiment of the present disclosure and is not therefore limiting the scope of the patent disclosure. Any equivalent structural change made under the inventive concept of the present disclosure using the contents of the present disclosure specification and drawings, or directly/indirectly applied in other related technical fields, is included in the scope of the patent protection of the present disclosure.

What is claimed is:

1. A color filter, comprising:
a substrate, defined with a first attachment region, a second attachment region, and a third attachment region;
a color filter layer, comprising a first color layer, a second color layer, and a third color layer, wherein the first attachment region is defined with the second color layer thereon, and the second color layer in the first attachment region is defined with the first color layer thereon, the second attachment region is defined with the second color layer thereon, and the third attachment region is defined with the third color layer thereon; and
a spacer, comprising a main spacer and an auxiliary spacer, wherein the main spacer is defined on an upper surface of the first color layer, the auxiliary spacer is defined on an upper surface of the second color layer in the second attachment region, and is defined on an upper surface of the third color layer in the third attachment region,
the height of the upper surface of the main spacer from the substrate is greater than the height of the upper surface of the auxiliary spacer from the substrate.

2. The color filter according to claim 1, wherein the upper surface of the second color layer defined in the second attachment region is higher than the upper surface of the third color layer defined in the third attachment region.

3. The color filter according to claim 1, wherein the first color layer is a blue layer, the second color layer is a green layer, and the third color layer is a red layer.

4. The color filter according to claim 1, wherein the first attachment region, the second attachment region, and the third attachment region are sequentially defined in parallel.

5. The color filter according to claim 1, wherein the heights of the upper surfaces of the first color layer, the second color layer, and the third color layer from the substrate decreases sequentially.

6. The color filter according to claim 5, wherein the upper surface of the auxiliary spacer defined in the second attachment region is higher than the upper surface of the auxiliary spacer defined in the third attachment region.

7. The color filter according to claim 1, wherein a black matrix layer is defined on the substrate, and the black matrix layer defines the first attachment region, the second attachment region, and the third attachment region on the substrate.

8. The color filter according to claim 1, wherein the height of the upper surface of the second color layer defined in the second attachment region from the substrate is greater than the height of the upper surface of the third color layer defined in the third attachment region from the substrate;
the first attachment region, the second attachment region, and the third attachment region are sequentially defined in parallel.

9. The color filter according to claim 1, wherein the upper surface of the second color layer defined in the second attachment region is higher than the upper surface of the third color layer defined in the third attachment region;
the upper surface of the first color layer defined in the first attachment region is higher than the upper surface of the second color layer defined in the second attachment region.

10. The color filter according to claim 9, wherein the upper surface of the auxiliary spacer defined in the second attachment region is higher than the upper surface of the auxiliary spacer defined in the third attachment region.

11. The color filter according to claim 1, wherein the upper surface of the second color layer defined in the second attachment region is higher than the upper surface of the third color layer defined in the third attachment region;
the upper surface of the first color layer defined in the first attachment region is higher than the upper surface of the second color layer defined in the second attachment region;
the first attachment region, the second attachment region, and the third attachment region are sequentially defined in parallel.

12. The color filter according to claim 11, wherein the first color layer is a blue layer, the second color layer is a green layer, and the third color layer is a red layer.

13. A method for manufacturing a color filter, wherein the method for manufacturing the color filter comprises the following steps:
exposing a third attachment region of a substrate to form the third color layer;
exposing the second attachment region and the first attachment region on the substrate to form the second color layer;
exposing the second color layer in the first attachment region on the substrate to form the first color layer;
exposing the first color layer in the first attachment region to form a main spacer, and exposing the second color layer in the second attachment region and the third color layer in the third attachment region to form an auxiliary spacer.

14. A display panel, comprising an array substrate and a color filter;
the color filter comprising:
a substrate, defined with a first attachment region, a second attachment region and a third attachment region;
a color filter layer, comprising a first color layer, a second color layer, and a third color layer, wherein the first attachment region is defined with the second color layer thereon, and the second color layer in the first attachment region is defined with the first color layer thereon, the second attachment region is defined with the second color layer thereon, and the third attachment region is defined with the third color layer thereon; and
a spacer, comprising a main spacer and an auxiliary spacer, wherein the main spacer is defined in an upper surface of the first color layer, the auxiliary spacer is defined in an upper surface of the second color layer in the second attachment region, and is defined in an upper surface of the third color layer in the third attachment region,
the height of the upper surface of the main spacer from the substrate is greater than the height of the upper surface of the auxiliary spacer from the substrate;
the array substrate abuts on one end of the main spacer away from the substrate.

15. The display panel according to claim 14, wherein the upper surface of the second color layer defined in the second attachment region is higher than the upper surface of the third color layer defined in the third attachment region;
the first attachment region, the second attachment region, and the third attachment region are sequentially defined in parallel.

16. The display panel according to claim 14, wherein the upper surface of the second color layer defined in the second attachment region is higher than the upper surface of the third color layer defined in the third attachment region;
the upper surface of the first color layer defined in the first attachment region is higher than the upper surface of the second color layer defined in the second attachment region.

17. The display panel according to claim 16, wherein the upper surface of the auxiliary spacer defined in the second attachment region is higher than the upper surface of the auxiliary spacer defined in the third attachment region.

18. The display panel according to claim 14, wherein the upper surface of the second color layer defined in the second attachment region is higher than the upper surface of the third color layer defined in the third attachment region;
the upper surface of the first color layer defined in the first attachment region is higher than the upper surface of the second color layer defined in the second attachment region;
the first attachment region, the second attachment region, and the third attachment region are sequentially defined in parallel.

19. The display panel according to claim 18, wherein the first color layer is a blue layer, the second color layer is a green layer, and the third color layer is a red layer.
